(19) United States
(12) Patent Application Publication
(10) Pub. No.: US 2023/0298825 A1
(43) Pub. Date: Sep. 21, 2023

(54) ORGANIC/INORGANIC COMPOSITE TRANSPORT LAYERS FOR BLOCKING IODINE DIFFUSION IN HALIDE PEROVSKITE ELECTRONIC DEVICES

(71) Applicant: The Trustees of Princeton University, Princeton, NJ (US)

(72) Inventors: Barry P. Rand, Princeton, NJ (US); Ross A. Kerner, Lakewood, CO (US); James C. Loy, Princeton, NJ (US)

(73) Assignee: The Trustees of Princeton University, Princeton, NJ (US)

(21) Appl. No.: 18/096,274

(22) Filed: Jan. 12, 2023

Related U.S. Application Data
(60) Provisional application No. 63/299,469, filed on Jan. 14, 2022.

(51) Int. Cl. H01G 9/20

(52) U.S. Cl. CPC H01G 9/2018; H01G 9/2009

(57) ABSTRACT

Compositions of matter and devices using those compositions are provided, which can, e.g., impede or restrict the migration of halides from a halide perovskite active layer. The composite material may include n layers of semiconductors, wherein n ≥ 2. Each layer of semiconductors may contain (i) one or more organic semiconductor layers and one or more inorganic semiconductor layer in contact with the one or more organic semiconductor layers, (ii) one or more composite semiconductor layers, each composite semiconductor layer containing an organic material and inorganic material, or (iii) a combination thereof.

### CROSS-REFERENCE TO RELATED APPLICATIONS

The present application claims priority to U.S. Provisional Pat. Application No. 63/299,469, filed Jan. 14, 2022, the contents of which are incorporated by reference herein in its entirety.

### TECHNICAL FIELD

The present application is drawn to halide perovskite electronic devices, and to the use of particular transport layers to block iodine diffusion in such devices in particular.

### BACKGROUND

This section is intended to introduce the reader to various aspects of art, which may be related to various aspects of the present invention that are described and/or claimed below. This discussion is believed to be helpful in providing the reader with background information to facilitate a better understanding of the various aspects of the present invention. Accordingly, it should be understood that these statements are to be read in this light, and not as admissions of prior art.

Halide perovskite devices are high performing but suffer from stability issues because a halide (e.g., iodine, bromine, etc.) is released from the perovskite active layer during operation. The halide often permeates the devices and corrodes the metals used as current collectors or wire leads.

The current best proposed solution is to use add a single inorganic blocking layer; however, inorganic layers cannot be directly deposited on top of the perovskite or have other chemical incompatibility issues. Further, any defects in the inorganic layer will rapidly transmit the halide or corroded metal cations.

### BRIEF SUMMARY

Various deficiencies in the prior art are addressed below by the disclosed compositions of matter and devices.

In some embodiments, a composite material is provided. The composite material may include n layers of semiconductors, where n ≥ 2. Each layer of semiconductors may include: (i) one or more organic semiconductor layers and one or more inorganic semiconductor layer in contact with the one or more organic semiconductor layers, (ii) one or more composite semiconductor layers, each composite semiconductor layer containing an organic material and inorganic material, or (iii) a combination thereof.

In some embodiments, each layer of semiconductors may be between 5 and 1000 nm thick. In some embodiments, at least one inorganic layer may include a metal oxide, which may be, e.g., MoOₓ, WOₓ, NiOₓ, or VOₓ. In some embodiments, at least one inorganic layer may include a chalcogenide, which may be, e.g., ZnS. In some embodiments, at least one inorganic layer may include a metal halide, which may be, e.g., CuI. In some embodiments, at least one inorganic layer may include a two-dimensional (2D) material, which may be, e.g., MoS₂, MoSe₂, WS₂, WSe₂, HfS₂, HfSe₂, hexagonal BN, or graphene. In some embodiments, at least one inorganic layer may be treated with a reductant (such as Yb or Al) to, e.g., assist in stabilizing the oxide against a halide (such as iodine or bromine). In some embodiments, at least one organic layer comprises a small molecule. In some embodiments, at least one organic layer comprises a polymeric p-type or hole conducting organic material, which may be, e.g., solution or vapor processed. In some embodiments, at least one composite semiconductor layer comprises a metal oxide and a polymeric p-type or hole conducting organic material.

In some embodiments, a halide perovskite electronic device may be provided. The halide perovskite electronic device may include a cathode, a metal anode, a perovskite active layer disposed between the cathode and the metal anode, and a composite material as disclosed herein. The composite material may be disposed between the metal anode or cathode and the perovskite active layer (which may include, e.g., iodine or bromine). The composite material may be arranged such that at least one of the organic semiconductor layers or composite semiconductor layers is between the perovskite active layer and any inorganic semiconductor layer present in the composite layer. In some embodiments, the halide perovskite electronic device may be a light-emitting diode (LED), a solar cell, a transistor, a laser, a photodetector, or an X-ray detector.

### BRIEF DESCRIPTION OF FIGURES

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 is a cross-sectional side view of an embodiment of a halide perovskite electronic device incorporating a composite material

FIGS. 2A, 2B, 2C, and 2D are cross-sectional side views of embodiments of composite materials.

FIG. 3 is an illustration of halide transport through an embodiment of a composite material.

FIG. 4A is a schematic of an Ag:I₂ corrosion test device for evaluating iodine diffusion rates through HTM thin films.

FIG. 4B is a graph showing conductance transients of an Ag resistor coated with poly-TPD or PVK after correcting for the ITO series resistance and photographs of the devices before and after I₂ exposure.

FIG. 5 is a graph showing Ag:I₂ test characterization of the influence annealing PMMA at 120° C. for 20 min (processed from a 10 mg/mL solution in chlorobenzene); ellipsometry measurements of thicker films revealed nearly 10% densification of the PMMA layer after annealing indicating physical properties and processing history also influence the I₂ permeability of organic layers.

FIG. 6 is a graph showing an Ag:I₂ corrosion test data for spiro-MeOTAD compared to spiro-MeOTAD/MoO₃ composite bilayer; the 15 nm thick MoO₃ layer offered significantly more protection from I₂ than spiro-MeOTAD alone.

FIG. 7 is a graph showing change in current (final - initial) of the as-deposited HTMs following exposing to I₂ vapor.

FIG. 8A is a schematic showing a device structure and measurement scheme where the iodine source is a MAPbI₃ film encapsulated by the HTM.

FIG. 8B is a graph showing absolute change in current (final measured 100 s after UV turned off) after UV illumination.

FIG. 9 is a series of graphs of representative current versus time measurements of MAPbI₃/P3HT/MoO₃ (first row), MAPbI₃/spiro-MeOTAD/MoO₃ (second row) MAPbI₃/Doped Spiro/MoO₃ (third row) MAPbI₃/Poly- TPD/MoO₃ (fourth row) MAPbI₃/PVK/MoO₃ (fifth row) devices before (left column), during (middle column), and after (right column) UV irradiation, where conductivity change is calculated by the difference of initial dark current before irradiation and the current measured at 100 s after the UV lamp switched off.

FIG. 10 is a series of graphs of current versus time measurements of MAPbI₃/MTDATA/MoO₃ (top row), MAPbI₃/NPB/MoO₃ (middle row), and MAPbI₃/TCTA/MoO₃ (bottom row) devices before (left column), during (middle column), and after (right column) UV irradiation. Conductivity change is calculated by the difference of initial dark current before irradiation and the current measured at 100 s after the UV lamp switched off.

FIG. 11 is a schematic of a sample used to measure loss of iodine from MAPbI₃ and subsequent transmission through an HTM to adsorb to Au.

FIG. 12 is a graph showing I₂ permeability constant of indicated solution processed and vacuum deposited HTMs versus their HOMO energy at I₂ partial pressure of approximately 0.2 Torr. Horizontal error bars reflect the standard deviation of (averaged) HOMO energies reported in literature and vertical error bars are calculated from statistical variation measured across several samples.

FIG. 13 is a flowchart of an embodiment of a method using the disclosed composite materials.

### DETAILED DESCRIPTION

The following description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for illustrative purposes to aid the reader in understanding the principles of the invention and the concepts contributed by the inventor(s) to furthering the art and are to be construed as being without limitation to such specifically recited examples and conditions. Additionally, the term, “or,” as used herein, refers to a non-exclusive or, unless otherwise indicated (e.g., “or else” or “or in the alternative”). Also, the various embodiments described herein are not necessarily mutually exclusive, as some embodiments can be combined with one or more other embodiments to form new embodiments.

The numerous innovative teachings of the present application will be described with particular reference to the presently preferred exemplary embodiments. However, it should be understood that this class of embodiments provides only a few examples of the many advantageous uses of the innovative teachings herein. In general, statements made in the specification of the present application do not necessarily limit any of the various claimed inventions. Moreover, some statements may apply to some inventive features but not to others. Those skilled in the art and informed by the teachings herein will realize that the invention is also applicable to various other technical areas or embodiments.

The disclosed architecture solves the stability issues by cutting off halide diffusion, preventing it from reaching the metals. The (organic/inorganic) n ≥ 2 preserves processing compatibility while retaining the high barrier properties for iodine transmission. The disclosed architecture will significantly improve the stability of perovskite devices and permit the use of non-noble metals which are also less expensive.

The layers used to build the disclosed composite can be, e.g., solution process from an ink (e.g., slot die coating, spin coating, spray coating), formed by reacting precursors on the sample (e.g., polymerization of organic monomers, sol gel of oxides, atomic layer deposition or CVD of inorganics), or vapor deposited. The disclosed approach does not rely on processing; it is the multilayer structure of the structure of the anode and, therefore, can be physically analyzed in any products.

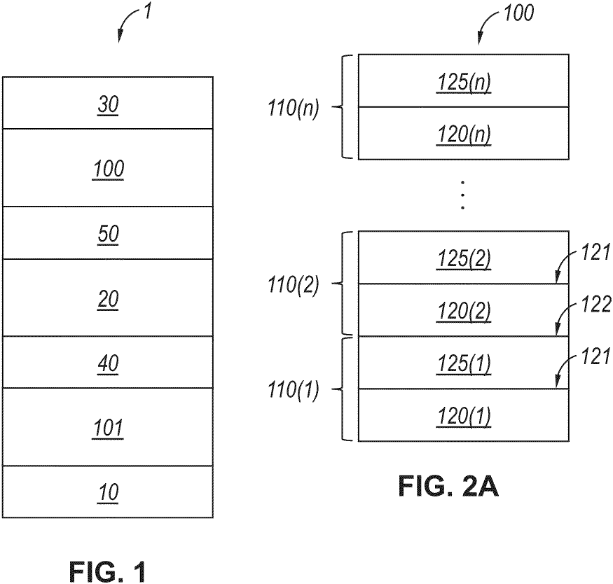

Referring to FIG. 1, in some embodiments, a halide perovskite electronic device may be provided. The halide perovskite electronic device 1 may include a cathode 10, a metal anode 30, and a perovskite active layer 20 disposed between the cathode and the metal anode. The perovskite active layer may include a halide, such as iodine or bromine. The device may include a composite material 100 disposed between the metal anode and the perovskite active layer. The device may include a composite material 101 disposed between the cathode and the perovskite active layer. As will be understood, the device may include one or two of the composite materials. When two composite materials are used, the two composite materials may be different. In some embodiments, only a composite material between the anode and the active layer is present (e.g., only composite material 100 is present). In some embodiments, only a composite material between the cathode and the active layer is present (e.g., only composite material 101 is present). In some embodiments, composite material 100 and composite material 101 are both present.

In FIG. 1, the composite material is shown as being between the metal anode and the active layer, but those skilled in the art will understand it can easily be placed on the other side of the active layer, between the active layer and the cathode, with minor modifications. For example, in various embodiments, the halogen-blocking structure can be configured to assist in electron transporting.

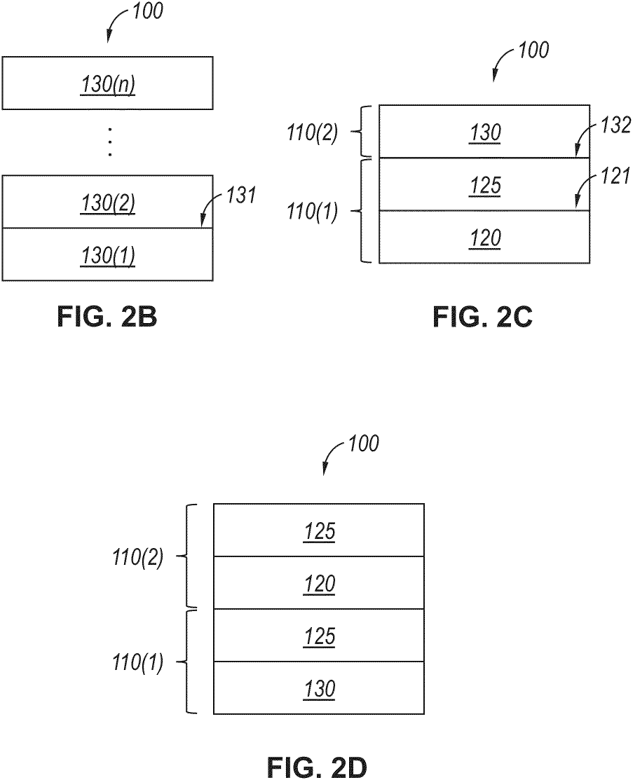

Referring to FIGS. 2A, 2B, 2C, and 2D, various embodiments of the composite material can be seen. The composite material may include n layers of semiconductors, where n ≥ 2. In some embodiments, each layer of semiconductors may be 5-1000 nm thick. In some embodiments, every layer has the same thickness. In some embodiments, one or more layers has a different thickness from one or more other layers.

In some embodiments, each layer may include one or more sublayers.

As seen in FIG. 2A, in some embodiments, in each layer 110, the composite material may include one or more organic semiconductor sublayers 120 (sometimes referred to as organic semiconductor layers) and one or more inorganic semiconductor sublayers 125 (sometimes referred to as inorganic semiconductor layers) in contact with the one or more organic semiconductor sublayers. Here, first layer 110(1) includes first organic semiconductor sublayer 120(1) at the bottom (e.g., in contact with the perovskite active layer) and first inorganic semiconductor sublayer 125(1) disposed on top of the first organic semiconductor sublayer. Similarly, second layer 110(2) includes a second organic semiconductor sublayer 120(2) at the bottom of the second layer, disposed on top of the first layer, and second inorganic semiconductor sublayer 125(2) disposed on top of the second organic semiconductor sublayer. This continues until n layers have been reached (see, e.g., nth layer 110(n), nth organic semiconductor sublayer 120(n) and nth inorganic semiconductor sublayer 125(n)).

In some embodiments, each inorganic sublayer may consist of a single inorganic material. In some embodiments, one or more inorganic sublayers may consist of a plurality of inorganic materials.

In some embodiments, at least one inorganic sublayer may include a metal oxide. Non-limiting examples of such metal oxides include MoOₓ, WOₓ, NiOₓ, and/or VOₓ. In some embodiments, at least one inorganic sublayer may include a chalcogenide. A non-limiting example of a chalcogenide that could be used is ZnS. In some embodiments, at least one inorganic sublayer may include a metal halide. A non-limiting example of a metal halide that could be used is CuI. In some embodiments, at least one inorganic sublayer may include a two-dimensional (2D) material. As used herein, 2D materials are understood materials that are only 1-2 atoms thick. Non-limiting examples of such 2D materials include MoS₂, MoSe₂, WS₂, WSe₂, HfS₂, HfSe₂, hexagonal BN, or graphene.

In some embodiments, at least one inorganic sublayer may be treated with a reductant (such as Yb or Al). This reductant may be used to, e.g., assist in stabilizing a metal oxide (e.g., MoOₓ, WOₓ, NiOₓ, and/or VOₓ) against a halide from the halide perovskite active layer.

In some embodiments, at least one organic sublayer comprises a small molecule. As used herein, small molecules are understood as being organic molecules with a molecular weight less than or equal to 1000 Daltons.

In some embodiments, each organic sublayer may consist of a single organic material. In some embodiments, one or more organic sublayers may consist of a plurality of organic materials.

In some embodiments, at least one organic sublayer comprises a polymeric p-type or hole conducting organic material, which may be, e.g., solution or vapor processed.

As seen in FIG. 2B, in some embodiments, each layer may include one or more composite semiconductor sublayers 130 (sometimes referred to as composite semiconductor layers), where each composite semiconductor sublayer contains an organic material and inorganic material. The organic and inorganic materials are mixed (generally heterogeneously); the composite semiconductor sublayers do not have alternating layers of organic and inorganic materials similar to the layers shown in FIG. 2A. For example, a composite material may include an organic material doped with a small amount of an inorganic material. Here, the first layer consists of first composite semiconductor sublayer 130(1), the second layer consists of second composite semiconductor sublayer 130(2), and the nth layer consists of nth composite semiconductor sublayer 130(n).

In some embodiments, the composite semiconductor sublayer consists of one organic material and one inorganic material. In some embodiments, the composite semiconductor sublayer consists of one or more organic materials and one or more inorganic materials. In some embodiments, the inorganic material(s) are present in each composite semiconductor sublayer in a total amount of no more than 50% by weight of the composite semiconductor sublayer. In some embodiments, the inorganic material(s) are present in each composite semiconductor sublayer in a total amount of no more than 40% by weight of the composite semiconductor sublayer. In some embodiments, the inorganic material(s) are present in each composite semiconductor sublayer in a total amount of no more than 30% by weight of the composite semiconductor sublayer. In some embodiments, the inorganic material(s) are present in each composite semiconductor sublayer in a total amount of no more than 20% by weight of the composite semiconductor sublayer. In some embodiments, the inorganic material(s) are present in each composite semiconductor sublayer in a total amount of no more than 10% by weight of the composite semiconductor sublayer. In some embodiments, the inorganic material(s) are present in each composite semiconductor sublayer in a total amount of no more than 5% by weight of the composite semiconductor sublayer.

In some embodiments, at least one composite semiconductor sublayer comprises a metal oxide and a transport layer, such as polymeric p-type or hole conducting organic material or a polymeric n-type of electron conducting organic material. As will be understood, typically p-type or hole conducting materials will be used when the composite semiconductor sublayer is between the anode and the perovskite active layer, and n-type or electron conducting materials will be used when the composite semiconductor sublayer is between the cathode and the perovskite active layer. However, there may be applications where it is beneficial to have this reversed, e.g., a p-type material between the active layer and the cathode and/or an n-type material between the active layer and the anode.

As seen in FIG. 2C, in some embodiments, the architecture may include some combination of the embodiments seen in FIGS. 2A and 2B. In FIG. 2C, the architecture is shown as including a first layer 110(1) composed of an organic semiconductor sublayer 120 below an inorganic semiconductor sublayer 125, and a second layer 110(2) composed of a composite semiconductor layer 130 disposed on the inorganic semiconductor sublayer. However, those of skill in the art will recognize that other combinations are envisioned.

The semiconductor layers 110 in the composite material 100 are generally arranged such that a halide migrating from the perovskite active layer will need to migrate through multiple layer interfaces (see, e.g., FIG. 2A, organic-to-inorganic layer interface 121 and inorganic-to-organic layer interface 122; FIG. 2B, composite semiconductor layer-to-composite semiconductor layer interface 131; FIG. 2C, inorganic layer-to-composite semiconductor layer interface 132.) In some embodiments, at least one of the organic semiconductor sublayers or composite sublayers is disposed between the perovskite active layer and any inorganic semiconductor layer in the composite material.

For example, as seen in FIG. 2D, a first layer 110(1) is shown as being composed of an inorganic sublayer 125 disposed on a composite semiconductor sublayer 130, and a second layer 110(2) composed of an inorganic sublayer 125 disposed on an organic sublayer 120. When a composite semiconductor layer is disposed on the perovskite active layer, the organic material(s) are preferably present in a total amount of at least 50% by weight of that composite semiconductor layer.

In some embodiments, every layer in the composite material is identical (e.g., any sublayers are identical, etc.). In some embodiments, at least one layer in the composite material is different from at least one other layer in the composite material. In some embodiments, at least one layer in the composite material has a different thickness compared to at least one other layer in the composite material. In some embodiments, at least one sublayer in the composite material is different from at least one other sublayer of the same type (e.g., a first organic semiconductor sublayer vs. a second organic semiconductor sublayer, a first inorganic semiconductor sublayer vs. a second inorganic semiconductor sublayer, and/or a first composite semiconductor sublayer vs. a second composite semiconductor sublayer). For example, a first organic semiconductor sublayer may have a different thickness and/or composition from a second organic semiconductor sublayer.

Referring to FIG. 1, as will be understood, the electronic device may include one or more additional layers based on the intended functionality of the device. For example, the device may include one or more layers 40 between the cathode and the perovskite active layer, and/or one or more layers 50 between the perovskite active layer and the composite material. These layers may include, e.g., hole injection layers, hole transport layers, electron injection layers, and electron transport layers. For example, in some embodiments, an electron injection layer may be disposed between the cathode and the perovskite active layer, and an electron transport layer may be disposed between the electron injection layer and the perovskite active layer. Similarly, a hole injection layer may be disposed between the anode and the perovskite active layer, and a hole transport layer may be disposed between the hole injection layer and the perovskite active layer. Such additional layers are well-known in the art, and methods for incorporating such layers into various devices are readily understood.

When the composite material is positioned on the anode side of the active layer, the combination of anode and composite material may sometimes be referred to herein as an “anode architecture”. When the composite material is positioned on the cathode side of the active layer, the combination of cathode and composite material may sometimes be referred to herein as an “cathode architecture”.

The disclosed architecture can be used in any halide perovskite (typically containing iodide) optoelectronic device application including LEDs, solar cells, transistors, lasers, photodetectors, and X-ray detectors.

Variations of this composite may be used as an encapsulation to protect materials from iodine corrosion in any other non-electronic application as well. The disclosed approach will make perovskites a commercially viable technology.

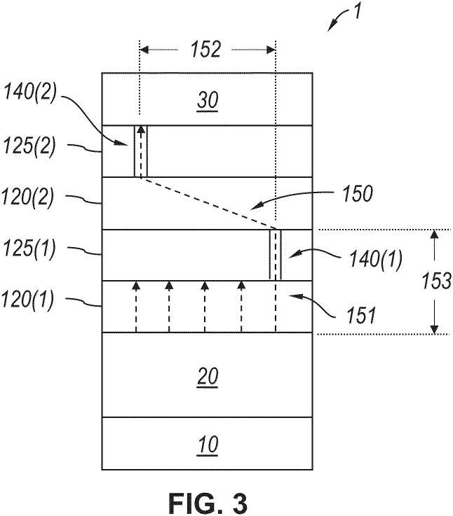

Referring to FIG. 3, it can be seen that halides from the perovskite may rapidly permeate a first organic layer 120(1) with suitable energetics for perovskite device anode architectures (see dashed arrows). A perfect inorganic layer is much less permeable, if not impermeable, to the halide. However, inorganic layers typically have one or more defects that the halide can enter through. As seen in FIG. 3, the first inorganic semiconductor sublayer 125(1) has a first pinhole 140(1) through which the halide can enter. Simply adding a second organic semiconductor sublayer 120(2) does not impede the halide mobility – as noted above, if the layer has suitable energetics, the halide will rapidly permeate through the layer. Thus, by adding a second inorganic semiconductor sublayer 125(2), the total path length 150 from the perovskite active layer to the anode is substantially lengthened, as the probability of a defect (such as second pinhole 140(2)) in the second inorganic semiconductor sublayer aligning with the defect in the first inorganic semiconductor sublayer is incredibly low. That is, the distance between defects in the direction 152 parallel to the surface of the composite material that faces the perovskite layer (e.g., the distance in an x-y plane) is typically about 10-1000 times the thickness 153 of the first layer. So, by adding a second inorganic semiconductor sublayer, the total path length 150 of the halide migrating away from the perovskite layer is at least 10 times (and may be, e.g., 10-10,000, 10-5,000, 10-2,000, or 10-1,000 times) the path length 151 that would exist if only the first layer (first organic semiconductor sublayer and first inorganic semiconductor sublayer) and the second organic semiconductor sublayer were present. Adding more layers (e.g., more organic and inorganic semiconductor sublayers, more composite semiconductor sublayers, etc.) increases the path length even further, greatly reducing the ability of the halide to be transported from the perovskite active layer to the anode.

Halide perovskite materials degrade under individual or combined stressors including visible light illumination, elevated temperature, electron beams, and X-ray irradiation, inducing substantial release of HI and molecular I₂. These species are extremely corrosive and known to compromise device performance and stability due to iodization of the metal electrode. The metal can be protected by a buffer layer that is less permeable to iodide/iodine (e.g., MoO3/Al or Cr₂O₃/Cr), but the details of iodide/iodine permeation throughout the device should still be considered. High solubility/permeability of and doping by I₂ in organic semiconductors is often overlooked, leading to perovskite device models that focus on ion accumulation at interfaces. Interface accumulation incompletely describes the ensemble of microscopic processes occurring, the most salient being electric field-independent diffusion of net-neutral charged iodide/hole or triiodide/hole pairs within the organic hole transport material (HTM). Halide perovskite technologies can benefit from measurement techniques that characterize iodide/iodine diffusion rates as well as elucidate ionic speciation and reaction mechanisms influencing mass transport kinetics.

In some examples, the electrical calcium corrosion test was adapted by replacing the Ca thin film with Ag, enabling the quantification of mass transport of iodine through HTMs commonly used in halide perovskite devices. The Ag resistor is sensitive to corrosion by I₂ but unreactive towards H₂O and O₂, allowing measurements in atmosphere. By varying the device configuration, one can examine 1) I₂ vapor transmission rates and permeability constants, 2) oxidation/doping by I₂ vapor exposure, and 3) doping by iodine-containing species sourced from in situ perovskite degradation.

Generally, and independent of molecular or polymeric structure, HTMs with low ionization energy < 5.4 eV (referenced to vacuum), dictated by the highest occupied molecular orbital (HOMO) energy, were observed to more rapidly transmit I₂ due to a doping reaction that facilitates uptake of a large amount of triiodide. The doping reaction is much less favorable for deeper HOMO energies (> 5.4 eV) resulting in lower concentrations and fluxes of I₂ species.

This relationship holds when iodide/iodine species are released at a methylammonium lead triiodide (MAPbI₃)/HTM interface under UV illumination. Thus, while pinholes and grain boundaries remain viable routes for iodine transport through HTMs and must be mitigated, this data asserts that HTM HOMO energy is an intrinsic parameter that determines the rate of transport through the HTM bulk. Critically, these results indicate that HTM HOMO energy may impact stability of a halide perovskite device in addition to initial performance; the HOMO should be well-matched to the perovskite valence band maximum for efficient hole collection and be as deep as is feasible to slow degradation caused by iodine diffusion.

### I₂ Permeability Constant Measurement

First, I₂ vapor transmission rates were characterized through small molecule and polymeric HTMs (See Table 1, below) (HTM abbreviations, structures, and HOMO energies tabulated in Supporting Information Table S1) using a modified Ca corrosion test.

TABLE 1

HTM abbreviations, material description, and HOMO energies

| HTM Abbreviation | Hole Transport Material | HOMO (eV) |
|---|---|---|
| P3HT | poly(3-hexylthiophene-2,5-diyl) (M_{w}~ 50,000-75,000) | 4.94 (0.15) electrochemically |
| MTDATA | 4,4′,4″-tris[(3-methylphenyl) phenylamino] triphenylamine (M_{w}~789.02) | 5.04 (0.08) UPS |
| Spiro-MeOTAD or spiro | 2,2′,7,7′-Tetrakis(N,N-di-p-methoxyphenylamino)-9,9′-spirobifluorene (M_{w}~1225.43) | 5.12 (0.06) electrochemically |
| poly-TPD | Poly(N,N′-bis(4-butylphenyl)-N,N′-bisphenylbenzidine) (Mw~10,000-120,000) | 5.28 (0.07) electrochemically |
| NPB | N,N′-bis(naphthalen-1-yl)-N,N′-bis(phenyl)-benzidine (M_{w}~588.74) | 5.49 (0.10) UPS |
| TCTA | 4,4′,4″-Tris(carbazol-9-yl) triphenylamine (M_{w}~740.89) | 5.73 (0.12) UPS |
| PVK | poly(9-vinylcarbazole) (M_{w}~1,100,000) | 5.72 (0.11) UPS |
| PMMA | Poly(methyl methacrylate) (M_{w}~120,000) | 8.5 |

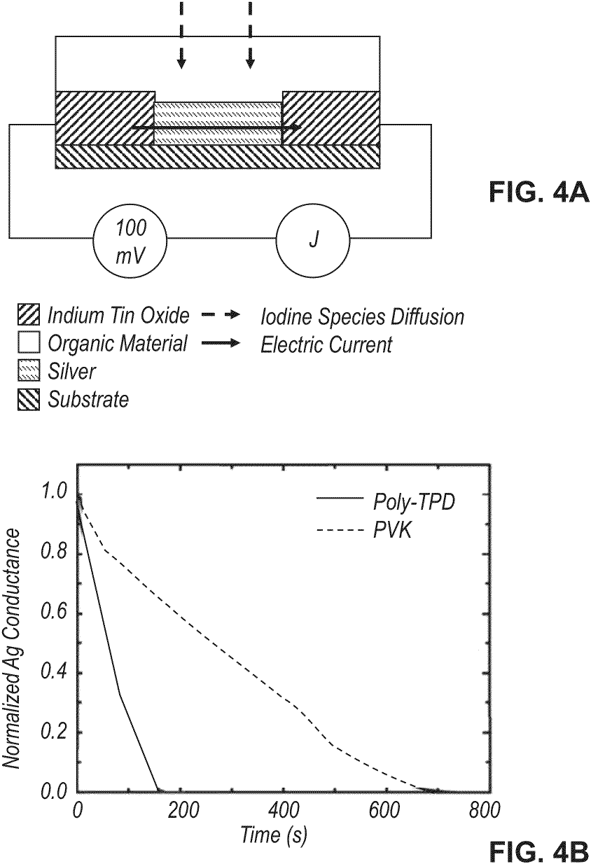

The device structure, shown in FIG. 4A, consists of a 30 nm thick Ag thin film resistor bridging a 5 mm wide channel between prepatterned indium tin oxide (ITO) electrodes. The HTMs were deposited on top of the Ag sensor by thermal evaporation or spin coating from solution. Specifically, a thin film (30 nm) of Ag was thermally evaporated through a shadow mask forming bridges between ITO electrodes (Colorado Concept Coatings, USA) with a channel spacing of 5 mm. For each device, one of the HTMs was either thermally evaporated from an Angstrom vacuum chamber (base pressure ~5×10⁻⁷ Torr) or spin-coated from solution on top of the entire substrate.

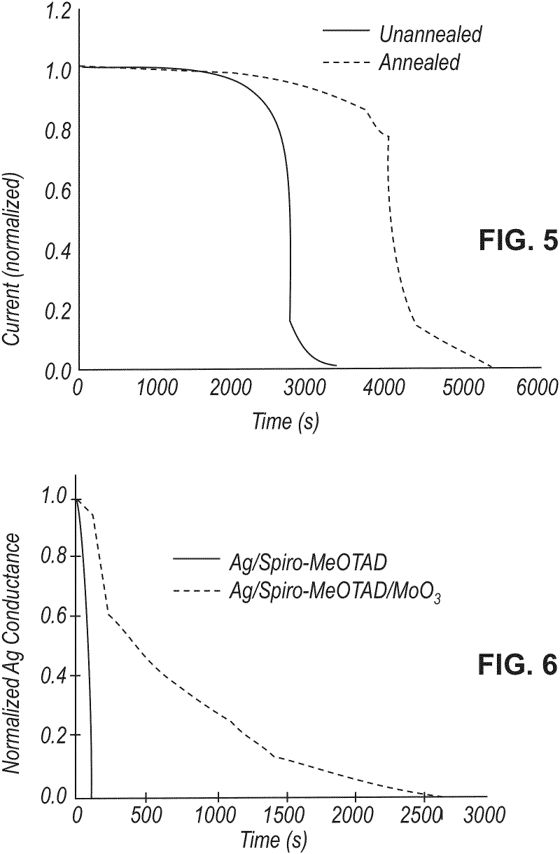

Transmission rates were measured by monitoring the current at 0.1 V bias as a function of time after exposure to I₂ vapor (partial pressure approximately 0.2 Torr at STP). Representative transients in the Ag conductance are shown for poly(vinylcarbazole) (PVK) and poly(N,N′-bis(4-butylphenyl)-N,N′- bisphenylbenzidine) (poly-TPD) in FIG. 4B. Correcting for the ITO series resistance (≈ 40 Ω) shows the Ag (≈ 2-4 Ω) conductance falls linearly with time suggesting steady-state conditions are established quasi-instantaneously (compared to the time scale of our measurements) and Fick’s first law dictates the flux of I₂ species. Fickian behavior was observed for the polymers and small molecule organics with shallow HTMs; deviations from Fick’s laws were observed for NPB and TCTA, which may arise from morphological weak points dominating diffusion at early times since bulk transmission is lower for deep HOMO energy materials. This simple test proved useful to characterize factors that improve I₂ barrier properties of organic materials, such as densification of poly(methyl methacrylate) (PMMA) by annealing (see FIG. 5), as well as use of organic HTM/MoO₃ composite bilayers (see FIG. 6) making it generally attractive for understanding iodine-induced degradation.

Membrane diffusion model calculations suggest Fick’s first law dominates measurements for the HTM thicknesses used here which are relevant for perovskite devices. The iodine flux, F, for this system is simply:

$$F = \frac{\left({C}_{0} - {C}_{L}\right) D}{L} \qquad \text{(1)}$$

where C₀ is the equilibrium concentration of iodine in the HTM just within the surface (assuming reaction with I₂ vapor is fast), C_{L} is the concentration at the HTM/Ag interface which is assumed to be zero given a fast reaction between Ag and I₂ at room temperature (uncoated Ag sensors degraded in less than 10 s), D is the diffusion coefficient, and L is the HTM thickness. From Eq. 1, it is established that the measurement cannot deconvolute C₀D (extracted from the slope in FIG. 4B).

Further calculations suggest that Fick’s second law dynamics will display a “lag time” as the HTM uptakes I₂ during the establishment of steady-state gradients. The relationship for total amount of diffusion species crossing the boundary at x = L from “Mathematics of Diffusion” by Crank was used (see below):

$$\begin{matrix}Q \left(t\right) = \\ \frac{D \left({C}_{0} - {C}_{L}\right) t}{L} + \frac{2 L}{π} {\sum }_{n = 1}^{∞} \frac{{C}_{0} {\left(- 1\right)}^{n} - {C}_{L}}{{n}^{2}} \left\{1 - exp \left(- \frac{D {n}^{2} {π}^{2} t}{{L}^{2}}\right)\right\} + \\ \frac{4 {C}_{i} L}{{π}^{2}} {\sum }_{m = 1}^{∞} \frac{1}{{\left(2 m + 1\right)}^{2}} \left\{1 - exp \left(- \frac{D {\left(2 m + 1\right)}^{2} {π}^{2} t}{{L}^{2}}\right)\right\}\end{matrix}$$

The math is greatly simplified by initial concentration, Cᵢ, and the concentration at the Ag interface, C_{L}, are both zero. Simulations using D = 10⁻⁹ cm²/s and C₀ = 10²⁰ atoms/cm³ suggest that these parameters cannot be easily deconvoluted unless the knee due to “lag” or “fill” time is long which requires the HTM to be many µm thick. These thicknesses are not relevant for perovskite devices and the properties of films processed to be this thick may deviate significantly from the properties of a thin film (< 300 nm). Furthermore, C₀ of 10²⁰ atoms/cm³ approaches the molecular density of the HTM representing full saturation; smaller C₀ and larger D would make it even more difficult to resolve the knee. Thus, for these example simulations, it was opted to use permeability constant.

The calculations show this may manifest for HTM thicknesses > 5 µm if D and C₀ are of order 10⁻⁹ cm²/s and 10²⁰ atoms/cm³, respectively, which are reasonable upper limits of these parameters. It may be possible to decouple C₀ from D for such a thick HTM barrier, but the properties likely differ substantially from the thin film counterparts. The example thin samples cannot quantify D and C₀, so permeability constant was used to describe the I₂ flux per Eq. 2:

$$Q \left(t\right) = \frac{P \text{Δ} p t}{L} \qquad \text{(2)}$$

Where Q(t) is the total amount of I₂ through the barrier, P is the permeability constant, t is time, L is the HTM thickness, and the pressure differential, Δp, is taken to be 0.2 Torr (the STP partial pressure of I₂). P can be easily obtained since Q(t_{final}) is equal to the moles of Ag/cm² determined by the Ag thickness and assumed density of 10.49 g/cm³.

Ag:I₂ corrosion tests were carried out on a number of spin coated and vapor deposited organic HTMs as well as insulating PMMA. All films were processed at room temperature without annealing. Measured permeability constants were plotted as a function of HTM HOMO energy; values of P vary nearly 3 orders of magnitude and are inversely correlated to HOMO level. Notably, the trend appears to be independent of processing method (spin coated versus vacuum deposited) and molecular/polymeric structure (compare spiro-MeOTAD, poly-TPD, and PVK). However, while the HOMO energy determines the magnitude of P, it is important to note that processing details and physical properties also influence P. For instance, P of polymers was slightly decreased following densification by annealing near the glass transition temperature (see FIG. 5). Importantly, a color change of the poly-TPD film was seen, indicative of a reaction simultaneously creating triiodide ions (iodide will become triiodide in the presence of excess I₂) and [poly-TPD]⁺ polarons; HTM oxidation was confirmed by UV-Vis absorbance measurements of spiro-MeOTAD films exposed to I₂.

### HTM Oxidation/Doping by I₂

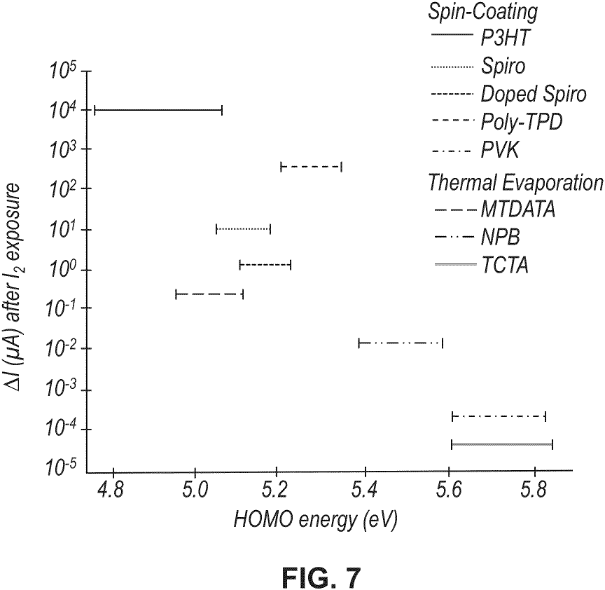

It is well-known that organic semiconductors can be oxidized (p-doped) by a reaction with I₂ vapor. Simply omitting the Ag resistor in the Ag:I₂ test geometry, lateral devices (20 µm channel) of as-deposited, undoped HTMs between ITO electrodes were fabricated (similar to that seen in FIG. 4A, but with no silver between the electrodes) to monitor conductance changes during oxidation/doping reactions with I₂ vapor. The change in electrical conductance after I₂ vapor exposure is plotted versus HOMO energy in FIG. 7. The magnitude of conductance change (and, indirectly, doping concentration) depends strongly on the HOMO energy; shallow HOMO energy materials are more strongly oxidized by I₂ (here, directly extracting I₂ doping concentration as carrier mobility in organic semiconductors could not be completed due to Poole-Frenkel and trap-charge limited transport effects). This observation rationalizes the relationship between HOMO and permeability constant in FIG. 4A; a strong reaction likely induces a larger concentration gradient and P (for now it is assumed that D is similar magnitude for various HTMs).

Single and multiple electron reduction/oxidation mechanisms of iodine / diiodide / triiodide / iodide are numerous and complex and the exact potentials will additionally depend on the solvation environment in the organic solid. Therefore, the kinetic mechanism that determines the potential/HOMO energy threshold for a reaction with I₂ could not be quantified, but it should be noted that the primary iodine speciation in the HTM is most likely triiodide as reported by others for poly(3-octylthiophene) doped by I₂ at a ratio of I₂ molecules: monomer units ≈ 1:37. I₂ vapor doping experiments indicate that only a very deep HOMO > 5.4 eV, deeper than nearly all diiodide radical anion (I₂/I₂^{-•}) and triiodide (I₂/I₃⁻) redox potentials, will prevent all possible reactions with I₂ vapor, minimize I₂ uptake by the HTM, and decrease I₂ permeation rates.

### Iodine Species Sourced From Perovskite

The Ag:I₂ test critically reveals iodine permeability dependence on HOMO energy when I₂ vapor was the reactant. The study can be extended to confirm the same trends are observed in a solid-state device where iodine-containing species are released during degradation of the halide perovskite active layer. Molecular I₂ is a proposed degradation product; moreover, I⁰ radicals and HI are likely to be released prior to or simultaneously with I₂, although it should be noted that HI can readily decompose to I₂. It is hypothesized that a strong doping reaction between I₂ vapor and an HTM may exacerbate reactions at the perovskite/HTM interface resulting in larger amounts of triiodide uptake by the HTM (conversely, iodide loss from the perovskite) and faster permeation of triiodide throughout the device.

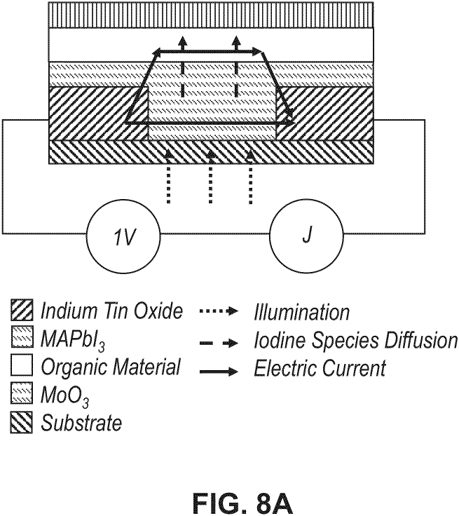

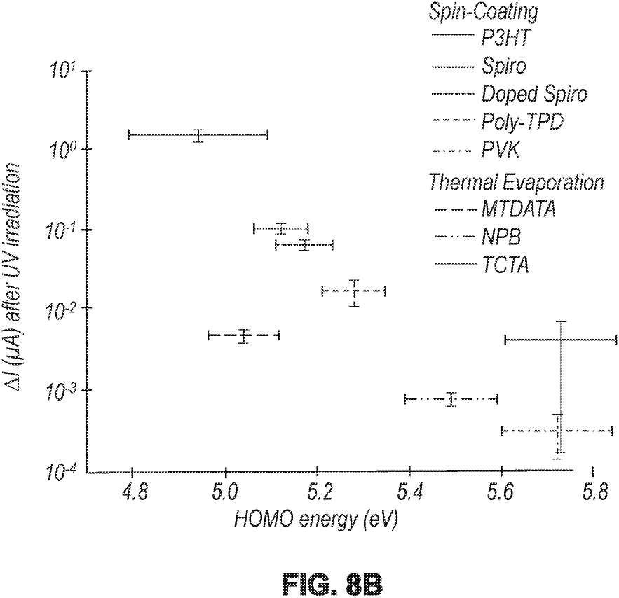

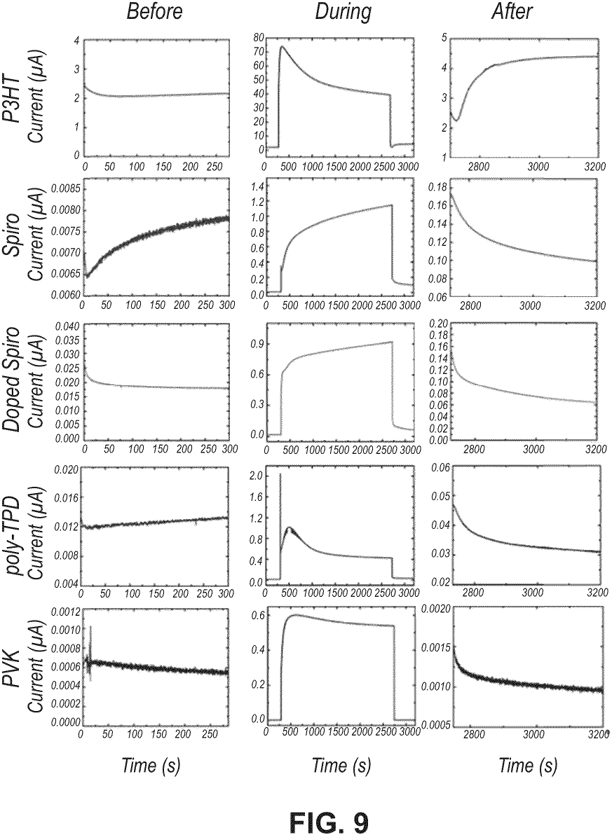

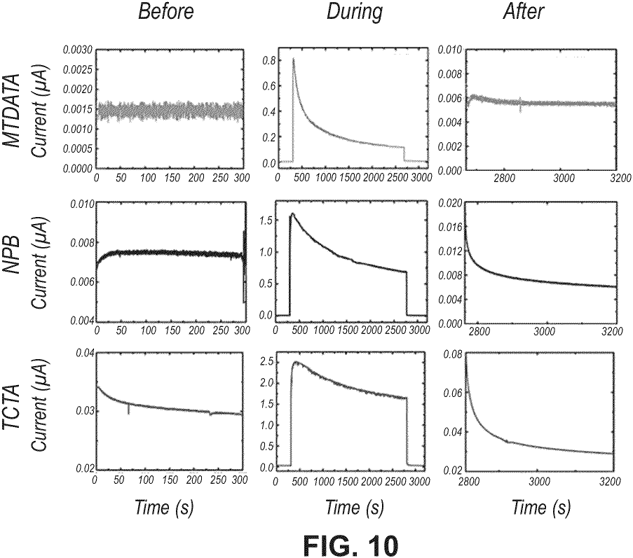

Current across lateral devices consisting of MAPbI₃/HTM/MoO₃ thin film stacks (see FIG. 8A) was measured before, during, and after 40 min of UV illumination to induce the release of photolysis products. MoO₃ served to prevent loss of I₂ to the environment, see, e.g., FIG. 6. In this device configuration, many HTM choices resulted in a large increase in conductance that persisted for long times (See FIGS. 9 and 10), which was not observed for control devices. We mainly attribute the conductance increase to volatile HI and iodine-containing species photolyzed from the MAPbI₃ that quasi-irreversibly dope the HTM, similar to what has been induced electrochemically.

Changes in absolute current after UV-irradiation are plotted versus HOMO of the HTM in FIG. 8B. Note the change in absolute current is similar for undoped and doped spiro-MeOTAD showing the total amount of products reacted was the same in both cases, and, thus, irrespective of initial doping. This measurement reveals the relationship between HOMO level and doping by iodine species is maintained when the iodide originates from an interface with perovskite. Thus, shallow HOMO HTMs like P3HT and spiro-MeOTAD are more likely to facilitate loss of iodide from the perovskite, effectively transport iodine throughout the device, and affect performance. The HTM is simply doped, which may not be directly detrimental (the opposite may even be true) but accelerating perovskite decomposition and metal electrode corrosion pathways is expected to negatively impact device stability.

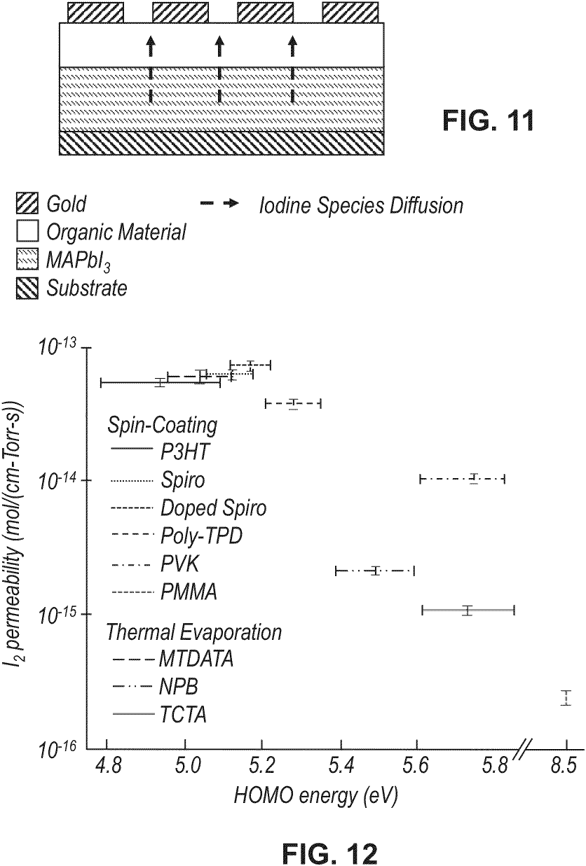

X-ray photoemission spectroscopy (XPS) was used to prove the perovskite degradation products contain iodine and confirm the transmission rate of such products depends on the HTM HOMO. Layer structures such as those shown in FIG. 11, consisting of fluorine-doped tin oxide (FTO)/MAPbI₃/poly-TPD or PVK (≈ 300 nm thick, unannealed)/Au (1 nm) were characterized by XPS where the X-ray irradiation induced in situ degradation. The thin, likely discontinuous Au served as an indicator as it irreversibly adsorbs iodine (without this indicator, iodine was lost to vacuum faster than it was generated and could not be detected). These materials are both polymeric, have high T_{g} (> 180° C.), and display vastly different I₂ vapor transmission rates (see FIGS. 4B and 12). Initially, the I 3d XPS signal is nearly zero for both samples. However, during X-ray irradiation, measurable amounts of iodine migrate through the poly-TPD to the Au. In contrast, the PVK, having a HOMO energy deeper than the 5.4 eV threshold, effectively blocks iodine transmission on this time scale. These results clearly demonstrate that iodine species can be lost from the perovskite and permeate the bulk of an HTM if the HOMO is < 5.4 eV.

### Implications for Devices

Performance and current-voltage characteristics of perovskite devices has been proposed to relate to HTM HOMO energy and its proximity to various iodine reduction potentials. The combined observations support and explain recent reports that halide species permeate the HTM bulk in appreciable concentrations. Thus, electrochemical features and current-voltage hysteresis are not limited to ion accumulation at perovskite/HTM interfaces, and the processes may be more complex than initially proposed. The results also indicate that HTM de-doping by iodide may be insignificant in solid-state perovskite devices where I₂ released from the perovskite instead contributes to further doping (see FIG. 8B). Ultimately, the ideal HTM should have as deep a HOMO as possible while still efficiently extracting holes from the perovskite. Long-term, I₂ permeation through organic HTMs may be inevitable in solar cells, though, since deep HOMO energy HTMs will not efficiently collect current due to a barrier for hole extraction. Buffer layers such as metal oxides, like are show for MoO₃, may effectively protect metal electrodes from iodine saturated HTMs.

Last, it is recognized that I₂ or I₃⁻ can induce bond breaking/forming chemical reactions in organic molecules and polymers. Poly(3-alkylthiophenes) doped by I₂ are known to deprotonate at the α-C leading to de-doping, HI release, and cross-linking. Indeed, following extended exposure to I₂ vapor (12 h) and removal of the I₂, poly(3-hexylthiophene) (P3HT) films became insoluble in chlorobenzene suggesting cross-linking occurred. Poly(dimethylsiloxane) (PDMS) also reacts chemically with I₂ becoming brittle. These observations exemplify the capability of iodine species within organic materials to drive more harmful chemistry than charge transfer and doping reactions. Thus, the combination of Ag:I₂ corrosion and I₂ vapor doping tests provide opportunities to reveal chemical impacts of iodine on organic hole and electron transport materials and encapsulants used in perovskite devices lending greater insight into potential degradation mechanisms.

It is found that transmission rate inversely correlates to the ionization/HOMO energy of the organic material. High I₂ permeability is additionally related to the ability of I₂ or I₂-like species to react with and dope shallow HOMO energy HTMs. Furthermore, the HOMO energy dependence was maintained in solid-state perovskite structures where MAPbI₃ degradation products induced by UV or X-ray irradiation were the only source of iodine. These insights firmly establish the influence of HTM HOMO energy on the rate of iodide diffusion in halide perovskite devices. As such, we introduce an additional design rule for HTMs — beyond pinholes and grain boundaries — to optimize device performance and stability by careful consideration of the HOMO energy to impede degradation pathways associated with halide migration.

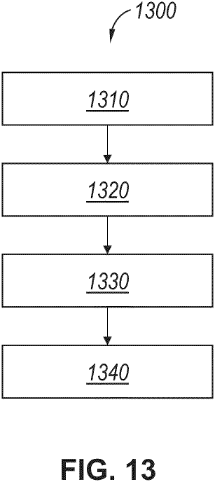

Thus, a method for impeding or inhibiting halide migration can be provided. Referring to FIG. 13, one particular embodiment of the method 1300 can be understood as activating 1310 a perovskite active layer, causing 1320 a halide from the perovskite active layer to migrate through an organic material from a first interfacial surface to a second interfacial surface, where the organic material has a HOMO greater than 5.4 eV, passing 1330 the halide through a first defect in an inorganic material to a third interfacial surface with an organic material. The method may include allowing 1340 the halide to then move through the organic material to a second defect extending through an inorganic material, where after passing the third interfacial surface, a distance the halide moves in a direction parallel to the surface of the perovskite active layer is at least 10 times (and may be, e.g., 10-10,000, 10-5,000, 10-2,000, or 10-1,000 times) the distance from the first interfacial surface to the third interfacial surface. By doing so, the ability of the halide to reach an anode through the organic/inorganic combination barrier can be greatly impeded.

Various modifications may be made to the systems, methods, apparatus, mechanisms, techniques and portions thereof described herein with respect to the various figures, such modifications being contemplated as being within the scope of the invention. For example, while a specific order of steps or arrangement of functional elements is presented in the various embodiments described herein, various other orders/arrangements of steps or functional elements may be utilized within the context of the various embodiments. Further, while modifications to embodiments may be discussed individually, various embodiments may use multiple modifications contemporaneously or in sequence, compound modifications and the like.

Although various embodiments which incorporate the teachings of the present invention have been shown and described in detail herein, those skilled in the art can readily devise many other varied embodiments that still incorporate these teachings. Thus, while the foregoing is directed to various embodiments of the present invention, other and further embodiments of the invention may be devised without departing from the basic scope thereof. As such, the appropriate scope of the invention is to be determined according to the claims.

What is claimed is:

1. A composite material, comprising:
n layers of semiconductors, each layer of semiconductors independently containing:
one or more organic semiconductor sublayers and one or more inorganic semiconductor sublayers in contact with the one or more organic semiconductor sublayers,
one or more composite semiconductor sublayers, each composite semiconductor sublayer containing an organic material and inorganic material, or
a combination thereof,
wherein n ≥ 2.

2. The composite material according to claim 1, wherein each layer of semiconductors is between 5 and 1000 nm thick.

3. The composite material according to claim 1, wherein at least one inorganic semiconductor sublayer comprises a metal oxide.

4. The composite material according to claim 3, wherein each metal oxide is MoOx, WOx, NiOx, VOx, TiOx, or SnOx.

5. The composite material according to claim 1, wherein at least one inorganic semiconductor sublayer comprises a chalcogenide.

6. The composite material according to claim 5, wherein at least one chalcogenide is ZnS.

7. The composite material according to claim 1, wherein at least one inorganic semiconductor sublayer comprises a metal halide.

8. The composite material according to claim 7, wherein at least one metal halide is CuI.

9. The composite material according to claim 1, wherein at least one inorganic semiconductor sublayer comprises at least one two dimensional (2D) material.

10. The composite material according to claim 9, wherein the at least one 2D material is MoS₂, MoSe₂, WS₂, WSe₂, HfS₂, HfSe₂, hexagonal BN, or graphene.

11. The composite material according to claim 1, wherein at least one inorganic semiconductor sublayer comprises an oxide, and the least one inorganic semiconductor sublayer is treated with a reductant to assist in stabilizing the oxide against a halide.

12. The composite material according to claim 11, wherein the halide is iodine or bromine.

13. The composite material according to claim 11, wherein the reductant is Yb or Al.

14. The composite material according to claim 1, wherein at least one organic semiconductor sublayer comprises a small molecule.

15. The composite material according to claim 1, wherein at least one organic semiconductor sublayer comprises at least one polymeric p-type or hole conducting organic material.

16. The composite material according to claim 15, wherein the at least one polymeric p-type or hole conducting organic material can be solution or vapor processed.

17. The composite material according to claim 1, wherein at least one organic semiconductor sublayer comprises at least one polymeric n-type or electron conducting organic material.

18. The composite material according to claim 17, wherein the at least one polymeric n-type or electron conducting organic material can be solution or vapor processed.

19. The composite material according to claim 1, wherein at least one composite semiconductor sublayer comprises a metal oxide and a polymeric p-type or hole conducting organic material.

20. A halide perovskite electronic device, comprising:
a cathode;
a metal anode;
a perovskite active layer disposed between the cathode and the metal anode; and
a composite material according to claim 1, the composite material being disposed between the metal anode or cathode and the perovskite active layer, arranged such that at least one of the organic semiconductor sublayers or composite semiconductor sublayers is between the perovskite active layer and any inorganic semiconductor sublayer of the composite material.

21. The halide perovskite electronic device according to claim 18, wherein the perovskite active layer comprises iodine or bromine.

22. The halide perovskite electronic device according to claim 18, wherein the halide perovskite electronic device is a light-emitting diode (LED), solar cell, transistor, laser, photodetector, or X- ray detector.
